(19) United States
(12) Patent Application Publication
(10) Pub. No.: US 2022/0293610 A1
(43) Pub. Date: Sep. 15, 2022

(54) MANUFACTURING METHOD OF SEMICONDUCTOR STRUCTURE AND SEMICONDUCTOR STRUCTURE

(71) Applicant: CHANGXIN MEMORY TECHNOLOGIES, INC., Hefei City (CN)

(72) Inventors: ER-XUAN PING, Hefei (CN); Jie Bai, Hefei (CN); Juanjuan Huang, Hefei (CN)

(21) Appl. No.: 17/575,815

(22) Filed: Jan. 14, 2022

Related U.S. Application Data
(63) Continuation of application No. PCT/CN2021/104433, filed on Jul. 5, 2021.

(30) Foreign Application Priority Data
Mar. 12, 2021 (CN) 202110271098.4

(51) Int. Cl. H01L 27/108; H01L 21/768

(52) U.S. Cl. CPC H01L 27/10885; H01L 21/7682; H01L 21/76852; H01L 21/76897; H01L 21/8239

(57) ABSTRACT

Provided are a manufacturing method of a semiconductor structure, and a semiconductor structure. The manufacturing method includes: providing a substrate; forming a plurality of bit line structures distributed at intervals on the substrate, each of the bit line structures including a conductive structure, a conductive barrier block and an insulative structure which are stacked sequentially, and the width of the conductive barrier block being less than the width of the conductive structure; and forming an air gap in contact with a side wall of each of the bit line structures.

### CROSS-REFERENCE TO RELATED APPLICATION(S)

This application is continuation of international application PCT/CN2021/104433, filed on Jul. 5, 2021, which claims priority to Chinese Patent Application No. 202110271098.4, filed with CNIPA on Mar. 12, 2021. The contents of international application PCT/CN2021/104433 and Chinese Patent Application No. 202110271098.4 are incorporated herein by reference in their entireties.

### BACKGROUND

A semiconductor memory includes a plurality of units, and each unit includes a capacitor, a transistor and a bit line. The capacitor is used to temporarily store data, and the transistor is used to control the bit line to write an electrical signal to the capacitor or read an electrical signal from the capacitor. As the size of a Dynamic Random Access Memory (DRAM) continuously decreases, the improvement of the performance of the bit line becomes more and more difficult.

### SUMMARY

This application relates to the technical field of semiconductor, and particularly relates to a manufacturing method of a semiconductor structure, and a semiconductor structure.

According to some embodiments, one aspect of this application provides a manufacturing method of a semiconductor structure.

The manufacturing method of the semiconductor structure includes:

a substrate is provided;

a plurality of bit line structures distributed at intervals are formed on the substrate, wherein each of the bit line structures includes a conductive structure, a conductive barrier block and an insulative structure which are stacked sequentially, and the width of the conductive barrier block is less than the width of the conductive structure; and

an air gap in contact with a side wall of each of the bit line structures is formed.

According to some embodiments, another aspect of this application further provides a semiconductor structure.

The semiconductor structure includes:

a substrate;

a plurality of bit line structures distributed at intervals on the substrate, wherein each of the bit line structures includes a conductive structure, a conductive barrier block and an insulative structure which are stacked sequentially, and the width of the conductive barrier block is less than the width of the conductive structure; and

an air gap in contact with a side wall of each of the bit line structures.

### BRIEF DESCRIPTION OF THE DRAWINGS

FIG. 1 is a flowchart of steps of a manufacturing method of a semiconductor structure according to an embodiment of this application.

FIG. 2 is a top view of a semiconductor structure according to an embodiment of this application.

FIG. 3 is a schematic diagram of steps of forming a bit line structure in the embodiment shown in FIG. 2.

FIG. 4 is a cross-sectional view taken along a line A-A′ in the embodiment shown in FIG. 2.

FIG. 5 is a schematic enlarged view of a part X in the embodiment shown in FIG. 4.

### DETAILED DESCRIPTION

For convenience of understanding of this application, this application will now be described more fully hereinafter with reference to the related drawings. Some implementation modes of this application are shown in the drawings. However, this application may be embodied in many different forms which are not limited to the embodiments described herein. On the contrary, the purpose of providing these implementation modes is to make the understanding of the disclosed contents of this application more thorough and comprehensive.

It should be noted that when a component is considered to be “fixed” to another component, the component may be directly fixed to another component or there may be an intermediate component. When a component is considered to be “connected” to another component, the component may be directly connected to another component or there may be an intermediate component at the same time. The terms “vertical”, “horizontal”, “left”, “right”, “up”, “down”, “front”, “rear”, “circumferential” and similar expressions used herein are based on the orientation or position relationships shown in the drawings. These terms are only for the convenience of describing this application and simplifying the description, but do not indicate or imply that the specified device or component must have a specific orientation and must be constructed and operated in the specific orientation, so that it can not be understood as a limitation to this application.

Unless defined otherwise, all technical and scientific terms used herein have the same meaning as commonly understood by those skilled in the art to which this application belongs. The terms used herein in the specification of this application is for the purpose of describing specific embodiments only and is not intended to limit this application. The term “and/or” as used herein includes any and all combinations of one or more related listed items.

As the size of the DRAM continuously decreases, the improvement of the performance of the bit line becomes more and more difficult.

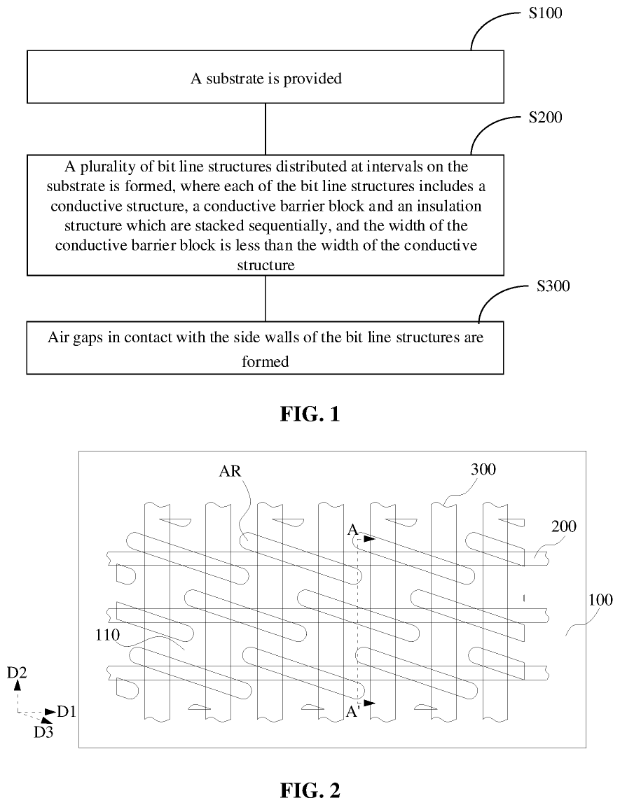

In view of the above, the embodiments of this application provide a manufacturing method of a semiconductor structure, and a semiconductor structure. Specifically, as shown in FIG. 1, in an embodiment, the manufacturing method of the semiconductor structure includes the following steps.

In S100, a substrate is provided.

The substrate may include a monocrystalline silicon substrate, a silicon-on-insulator (SOI) substrate, a stacked silicon-on-insulator (SSOI) substrate, a stacked silicon germanium-on-insulator (S-SiGeOI) substrate, a silicon germanium-on-insulator (SiGeOI) substrate, a germanium-on-insulator (GeOI) substrate, or the like. In the embodiments described in this application, the substrate includes a monocrystalline silicon substrate.

In some embodiments, referring to FIG. 2, trench isolation structures 110 may be arranged in a substrate 100 to define a plurality of active regions AR in the substrate 100, and the active regions AR may be arranged in a staggered array. Specifically, each trench isolation structure 110 includes silicon oxide, each active region AR may have a strip shape extending along a third direction D3, the active regions AR may be arranged in parallel to each other, and the center of one active region AR may be adjacent to the end of another adjacent active region AR.

In S200, a plurality of bit line structures distributed at intervals are formed on the substrate, each of the bit line structures includes a conductive structure, a conductive barrier block and an insulative structure which are stacked sequentially, and the width of the conductive barrier block is less than the width of the conductive structure.

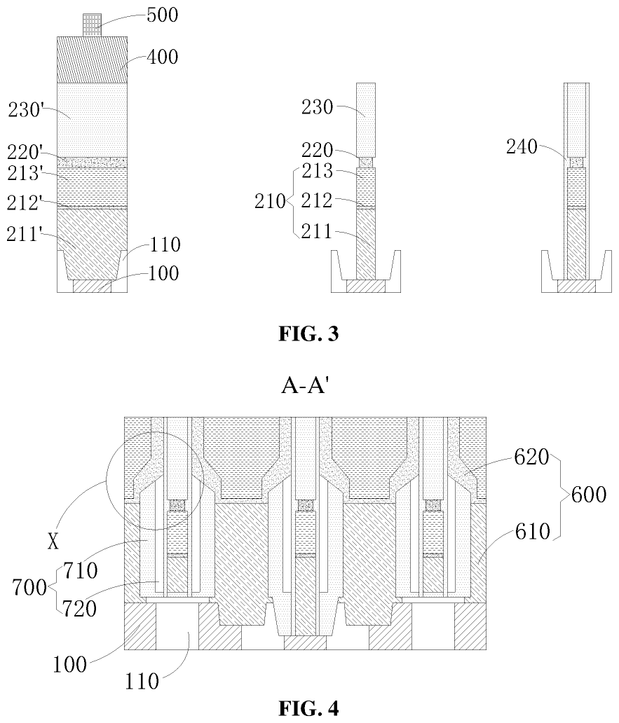

With continued reference to FIG. 2, a plurality of bit line structures 200 extending along a first direction D1 and a plurality of word line structures 300 extending along a second direction D2 are formed on the substrate 100. Specifically, as shown in FIG. 3, a bit line structure 200 includes a conductive structure 210, a first conductive barrier block 220 and an insulative structure 230 which are stacked sequentially. The conductive structure 210 is formed between the substrate 100 and the conductive barrier block 220, and includes a bit line plug 211, a conductive barrier layer 212 and a bit line 213 extending along a first direction D1, which are stacked sequentially. Isolation side walls 240 are also formed on the side faces of the conductive structure 210. The material of the isolation side walls 240 and the insulative structure 230 may be silicon nitride. The bit line plug 211 may be a polysilicon epitaxial layer. The conductive barrier layer 212 may be a titanium nitride layer. The material of the bit line 213 may be metal tungsten, aluminum, copper, nickel, cobalt, etc. The material of the conductive barrier block 220 may be metal-rich nitride or metal-rich silicide, such as tungsten nitride, molybdenum nitride, titanium nitride, titanium silicide, etc. It is there favorable for capturing the nitrogen atoms migrated from the insulative structure 230 into the conductive structure 210, and preventing the resistance of the conductive structure 210 from being increased due to nitridation of the conductive structure 210. Specifically, the metal-rich nitride means that the molar ratio of metal atoms to nitrogen atoms is greater than 1, such as 2, 3, 4, 5, 6, 7, etc., and the metal-rich silicide means that the molar ratio of metal atoms to silicon atoms is greater than 1, such as 2, 3, 4, 5, 6, 7, etc.

In some embodiments, the width of the conductive barrier block 220 is less than the width of the conductive structure 210. As shown in FIG. 2, the width of the conductive barrier block 220 and the conductive structure 210 represents the length along the second direction D2, and the second direction D2 is perpendicular to the extension direction D1 of the bit line structure 200.

In S300, air gaps in contact with the side walls of the bit line structures are formed. Specifically, as shown in FIG. 4, air gaps 720 in contact with the side walls of the bit line structures 200 are formed.

In the above manufacturing method of the semiconductor structure, by forming the conductive barrier block 220 between the conductive structure 210 and the insulative structure 230, the conductive structure 210 and the insulative structure 230 can be separated to prevent the resistance from being increased due to nitridation of some bit lines (such as metal tungsten) in the conductive structure 210 in the process of forming the insulative structure 230 (such as silicon nitride), thereby protecting the bit line 213 and also increasing the cross-sectional area of the conductor in the bit line structure 200, which is beneficial to further reduction of the resistance of the bit line structure 200. Furthermore, by forming the air gaps 720 in contact with the side walls of the bit line structures 200 and setting the width of the conductive barrier block 220 to be less than the width of the conductive structure, the reduction of the parasitic capacitance between the bit line structure 200 and the subsequent conductive plug is facilitated, thereby further improving the electrical performance of the semiconductor structure.

In an embodiment, as shown in FIG. 3, the above bit line structure 200 may be formed through the following steps:

In S210, a polysilicon epitaxial material layer 211′, a conductive barrier material layer 212′, a bit line material layer 213′, a conductive barrier block material layer 220′ and an insulative structure material layer 230′ are sequentially formed on the surface of the substrate 100 through a deposition process. The above deposition process may be a chemical vapor deposition process, a physical vapor deposition process or an atomic layer deposition process.

In S220, a mask layer 400 and a photoresist layer are formed on the insulative structure material layer 230′, the photoresist layer is exposed and developed to form a patterned photoresist layer 500, and the mask layer 400 is etched based on the patterned photoresist layer 500 to form a patterned mask layer.

In S230, the polysilicon epitaxial material layer 211′, the conductive barrier material layer 212′, the bit line material layer 213′, the conductive barrier block material layer 220′ and the insulative structure material layer 230′ are etched by taking the patterned mask layer as a mask to remove part of the polysilicon epitaxial material layer 211′, the conductive barrier material layer 212′, the bit line material layer 213′, the conductive barrier block material layer 220′ and the insulative structure material layer 230′, so as to form the above bit line structure 200.

In some embodiments, in order to make the width of the formed conductive barrier block 220 less than the width of the conductive structure 210, the S230 needs to meet the following condition: under the same etching conditions, the etching removal rates of the bit line material layer 213′ and the insulative structure material layer 230′ are both less than the etching removal rate of the conductive barrier block material layer 220′.

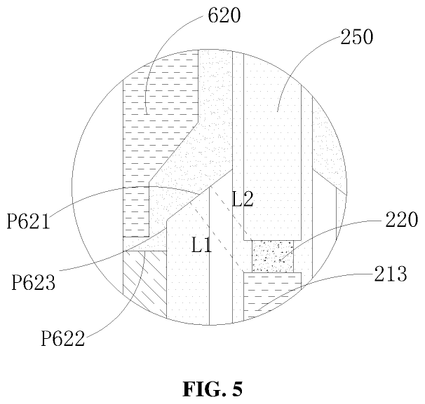

In an embodiment, as shown in FIG. 4 and FIG. 5, after the S200, the method further includes the following operation.

In S300, a conductive plug 600 including a first conductive part 610 and a second conductive part 620 is formed on the substrate 100 between adjacent bit line structures 200, and the second conductive part 620 is formed above the first conductive part 610. The bottom of the second conductive part 620 has an inclined face P621 facing the bit line structures 200.

As shown in FIG. 4, spacer layers 700 are also arranged on two sides of the bit line structure 200 to increase the insulation characteristics between the bit line 213 and the conductive plug 600. The spacer layer 700 may include an outer spacer layer 710 and an air gap 720, and the outer spacer layer 710 may be silicon nitride. Specifically, the top of the spacer layer 700 may be set as an inclined face, so that the bottom of the second conductive part 620 may also be correspondingly provided with an inclined face P621 facing the bit line structure 200 so as to be attached to the top inclined face of the spacer layer 700. In addition, the inclined face P621 of the second conductive part 620 is at least partially exposed to the air gap 720. By such arrangement, the parasitic capacitance between the bit line structure 200 and the adjacent conductive plug 600 can be reduced as much as possible. Furthermore, the arrangement of the inclined face P621 is favorable for increasing the contact area between the second conductive part 620 and a subsequent memory capacitor, thereby improving the electrical performance of the DRAM. In addition, the formation of the inclined face P621 at the bottom of the second conductive part 620 is also favorable for filling more conductive material between adjacent bit line structures 200 to increase the cross-sectional area of the conductive plug 600, thereby further reducing the resistance of the conductive plug 600. In some embodiments, there may be one or more inclined faces P621. When there are two inclined faces P621, as shown in FIG. 4, the inclined faces P621 are respectively located on two sides of the bottom of the second conductive part 620 facing adjacent bit line structures 200. In some embodiments, the inclined faces P621 may be symmetrically arranged on two sides of the bottom of the second conductive part 620 facing adjacent bit line structures 200, so as to be favorable for more fully using the space between adjacent bit line structures 200, thereby further increasing the conductive material filled between adjacent bit line structures 200.

In an embodiment, a forming method of an air gap 720 includes: a first dielectric layer, such as silicon oxide, is formed on a side face of a bit line structure 200; an outer spacer layer 710, such as silicon nitride, is formed on a side face of the first dielectric layer; and the first dielectric layer is removed by using the etching selection ratios of the first dielectric layer to the bit line structure 200 and the outer spacer layer 710 to form the air gap 720.

In an embodiment, as shown in FIG. 4 and FIG. 5, the bottom of the second conductive part 620 further includes a bottom face P622 and a vertical face P623 between the bottom face P622 and the inclined face P621. The bottom face P622 is in contact with a top face of the first conductive part 610, one end of the vertical face P623 is connected with the bottom face P622, and one end away from the bottom face P622 is connected with the inclined face P621. Specifically, the vertical face P623 is perpendicular to a plane where the first direction D1 and the second direction D2 are located. The arrangement of the vertical face P623 between the bottom face P622 and the inclined face P621 is favorable for the bottom of the second conductive part 620 to extend downward, so that more conductive material can be filled between adjacent bit line structures 200. In addition, the second conductive part 620 can be more stably arranged between the bit line structures, so that the conductive plug 600 has better structural stability.

In some embodiments, the vertical face P623 extends for a preset depth toward a direction close to the first conductive part 610. The vertical face P623 is controlled to downward extend for a preset depth, it is thereby favorable for achieving a balance between reducing resistance and ensuring the electrical performance of the semiconductor structure. Specifically, the preset depth is in a range from 10 nm to 100 nm.

In an embodiment, as shown in FIG. 5, a perpendicular distance L2 between a vertex angle of the conductive barrier block 220 and the inclined face P621 is less than a perpendicular distance L1 between a vertex angle of the conductive structure 210 and the inclined face P621. Both the L1 and the L2 are shown by dashed lines. By the above arrangement, the conductive barrier block 220 may have a certain thickness and width so as to be favorable for increasing the cross-sectional area of the conductive barrier block 220 as much as possible while meeting the condition that the width of the conductive barrier block 220 is less than that of the conductive structure 210, thereby increasing the cross-sectional area of the conductor in the bit line structure 200 to further reduce the resistance of the bit line structure 200.

In another embodiment, the perpendicular distance L2 between the vertex angle of the conductive barrier block 220 and the inclined face P621 is greater than the perpendicular distance L1 between the vertex angle of the conductive structure 210 and the inclined face P621. By the above arrangement, the cross-sectional area of the conductive barrier block 220 is increased so as to increase the cross-sectional area of the conductor in the bit line structure 200 to further reduce the resistance of the bit line structure 200, and furthermore, the distance between the conductive barrier block 220 and the second conductive part 620 can be increased as much as possible so as to reduce the parasitic capacitance between the conductive barrier block 220 and the second conductive part 620.

In some embodiments, as shown in FIG. 5, the top of the conductive barrier block 220 is higher than the bottom of the inclined face P621. The above arrangement is favorable for increasing the thickness of the conductive barrier block 220 as much as possible when the height of the bit line structure 200 is constant so as to further reduce the resistance of the bit line structure 200, and is also favorable for filling more conductive material between adjacent bit line structures 200 so as to further reduce the resistance of the conductive plug 600.

In some embodiments, the width of the conductive barrier block 220 is ⅓ to ½ of the width of the conductive structure 210. The above mode is favorable for forming a better support for an insulative structure 250 to improve the stability of the bit line structure 200, and can effectively reduce the parasitic capacitance between the bit line structure 200 and the conductive plug 600. When the ratio of the width of the conductive barrier block 220 to the width of the conductive structure 210 is less than ⅓, the conductive barrier block 220 is too narrow to form a better support for the insulative structure 250. When the ratio of the width of the conductive barrier block 220 to the width of the conductive structure 210 is greater than ½, the parasitic capacitance between the bit line structure 200 and the conductive plug 600 is easily increased, which is not conducive to the improvement of the electrical performance of the semiconductor structure.

The embodiments of this application further provide a semiconductor structure. Referring to FIG. 4, the semiconductor structure includes a substrate 100 and a plurality of bit line structures 200 distributed at intervals on the substrate 100. Each of the bit line structures 200 includes a conductive structure 210, a conductive barrier block 220 and an insulative structure 230 which are stacked sequentially, and the width of the conductive barrier block 220 is less than the width of the conductive structure 210. The semiconductor structure also includes air gaps 720 in contact with the side walls of the bit line structures 200.

The material of the conductive barrier block 220 may be metal-rich nitride or metal-rich silicide, such as tungsten nitride, molybdenum nitride, titanium nitride, titanium silicide, nickel silicide, cobalt silicide, etc., thereby being favorable for capturing the nitrogen atoms migrated from the insulative structure 230 into the conductive structure 210, and preventing the resistance of the conductive structure 210 from being increased due to nitridation of the conductive structure 210. Specifically, the metal-rich nitride means that the molar ratio of metal atoms to nitrogen atoms is greater than 1, such as 2, 3, 4, 5, 6, 7, etc., and the metal-rich silicide means that the molar ratio of metal atoms to silicon atoms is greater than 1, such as 2, 3, 4, 5, 6, 7, etc.

In the above semiconductor structure, by forming the conductive barrier block 220 for separating the conductive structure 210 and the insulative structure 230, the resistance can be prevented from being increased due to nitridation of some bit lines (such as metal tungsten) in the conductive structure 210 in the process of forming the insulative structure 230 (such as silicon nitride), thereby protecting the bit line 213 and also increasing the cross-sectional area of the conductor in the bit line structure 200, which is beneficial to further reducing the resistance of the bit line. Furthermore, by forming the air gaps 720 in contact with the side walls of the bit line structures 200 and setting the width of the conductive barrier block 220 to be less than the width of the conductive structure 210, the reduction of the parasitic capacitance between the bit line structure 200 and the subsequent conductive plug 600 is facilitated, thereby further improving the electrical performance of the semiconductor structure.

In an embodiment, as shown in FIG. 4, the above semiconductor structure further includes a conductive plug 600 located on the substrate 100 between adjacent bit line structures 200. The conductive plug 600 includes a first conductive part 610 and a second conductive part 620 above the first conductive part 610. The bottom of the second conductive part 620 has an inclined face facing the bit line structure 200, it is thereby favorable for increasing the contact area between the second conductive part 620 and the subsequent memory capacitor, so as to improve the electrical performance of the DRAM. In addition, the formation of the inclined face P621 at the bottom of the second conductive part 620 is also favorable for filling more conductive material between adjacent bit line structures 200 to increase the cross-sectional area of the conductive plug 600, thereby further reducing the resistance of the conductive plug 600. In some embodiments, two inclined faces P621 may be provided and are respectively located on two sides of the bottom of the second conductive part 620 facing adjacent bit line structures 200, so as to be favorable for more fully using the space between adjacent bit line structures 200, thereby further increasing the conductive material filled between adjacent bit line structures 200.

Spacer layers 700 are also arranged on two sides of the bit line structure 200 to increase the insulation characteristics between the bit line 213 and the conductive plug 600. The spacer layer 700 may include an outer spacer layer 710 and the air gap 720, and the outer spacer layer 710 may be silicon nitride. Specifically, the top of the spacer layer 700 may be set as an inclined face, so that the bottom of the second conductive part 620 may also be correspondingly provided with an inclined face P621 facing the bit line structure 200 so as to be attached to the top inclined face of the spacer layer 700. In addition, the inclined face P621 of the second conductive part 620 is at least partially exposed to the air gap 720. By such arrangement, the parasitic capacitance between the bit line structure 200 and the adjacent conductive plug 600 can be reduced as much as possible.

In an embodiment, the width of the conductive barrier block 220 is less than the width of the insulative structure 230. The above arrangement can further increase the distance between the bit line structure 200 and the subsequent conductive plug 600 to reduce the parasitic capacitance between the bit line structure 200 and the conductive plug 600, and is also favorable for reducing or eliminating the influence of the wide top and narrow bottom of the conductive barrier block 220 to improve the structural stability of the bit line structure 200.

In an embodiment, the bottom of the second conductive part 620 further includes a bottom face P622 and a vertical face P623 between the bottom face P622 and the inclined face P621. The bottom face P622 is in contact with the top face of the first conductive part 610, one end of the vertical face P623 is connected with the bottom face P622, and one end away from the bottom face P622 is connected with the inclined face P621. The arrangement of the vertical face P623 between the bottom face P622 and the inclined face P621 is favorable for the bottom of the second conductive part 620 to extend downward, so that more conductive material can be filled between adjacent bit line structures 200. In addition, the second conductive part 620 can be more stably arranged between the bit line structures, so that the conductive plug 600 has better structural stability. In some embodiments, the vertical face P623 extends for a preset depth toward a direction close to the first conductive part 610.

In an embodiment, as shown in FIG. 5, a perpendicular distance L2 between a vertex angle of the conductive barrier block 220 and the inclined face P621 is less than a perpendicular distance L1 between a vertex angle of the conductive structure 210 and the inclined face P621. Both the L1 and the L2 are shown by dashed lines. By the above arrangement, the conductive barrier block 220 may have a certain thickness and width so as to be favorable for increasing the cross-sectional area of the conductive barrier block 220 as much as possible while meeting the condition that the width of the conductive barrier block 220 is less than that of the conductive structure 210, thereby increasing the cross-sectional area of the conductor in the bit line structure 200 to further reduce the resistance of the bit line structure 200.

In another example, the perpendicular distance L2 between the vertex angle of the conductive barrier block 220 and the inclined face P621 is greater than the perpendicular distance L1 between the vertex angle of the conductive structure 210 and the inclined face P621. By the above arrangement, the cross-sectional area of the conductive barrier block 220 is increased so as to increase the cross-sectional area of the conductor in the bit line structure 200 to further reduce the resistance of the bit line structure 200, and furthermore, the distance between the conductive barrier block 220 and the second conductive part 620 can be increased as much as possible so as to reduce the parasitic capacitance between the conductive barrier block 220 and the second conductive part 620.

In some embodiments, as shown in FIG. 5, the top of the conductive barrier block 220 is higher than the bottom of the inclined face P621. The above arrangement is favorable for increasing the thickness of the conductive barrier block 220 as much as possible when the height of the bit line structure 200 is constant so as to further reduce the resistance of the bit line structure 200, and is also favorable for filling more conductive material between adjacent bit line structures 200 so as to further reduce the resistance of the conductive plug 600.

In some embodiments, the width of the conductive barrier block 220 is ⅓ to ½ of the width of the conductive structure 210. The above mode is favorable for forming a better support for the insulative structure 250 to improve the stability of the bit line structure 200, and can effectively reduce the parasitic capacitance between the bit line structure 200 and the conductive plug 600.

In some embodiments, the material of the conductive barrier block 220 may be metal-rich nitride or metal-rich silicide, such as tungsten nitride, molybdenum nitride, titanium nitride, titanium silicide, nickel silicide, cobalt silicide, etc., it is thereby favorable for capturing the nitrogen atoms migrated from the insulative structure 230 into the conductive structure 210, and preventing the resistance of the conductive structure 210 from being increased due to nitridation of the conductive structure 210. Specifically, the metal-rich nitride means that the molar ratio of metal atoms to nitrogen atoms is greater than 1, such as 2, 3, 4, 5, 6, 7, etc., and the metal-rich silicide means that the molar ratio of metal atoms to silicon atoms is greater than 1, such as 2, 3, 4, 5, 6, 7, etc.

The technical features of the above embodiments can be combined arbitrarily. In order to make the description concise, all possible combinations of various technical features in the above embodiments are not completely described. However, as long as there is no contradiction in the combination of these technical features, it should be regarded as the scope of this specification.

What is claimed is:

1. A manufacturing method of a semiconductor structure, comprising:
providing a substrate;
forming a plurality of bit line structures distributed at intervals on the substrate, wherein each of the bit line structures comprises a conductive structure, a conductive barrier block and an insulative structure which are stacked sequentially, and a width of the conductive barrier block is less than a width of the conductive structure; and
forming an air gap in contact with a side wall of each of the bit line structures.

2. The manufacturing method of the semiconductor structure of claim 1, further comprising:
forming a conductive plug comprising a first conductive part and a second conductive part on the substrate between adjacent bit line structures, wherein the second conductive part above the first conductive part,
wherein a bottom of the second conductive part has an inclined face facing the bit line structures.

3. The manufacturing method of the semiconductor structure of claim 2, wherein
the bottom of the second conductive part further comprises a bottom face and a vertical face between the bottom face and the inclined face, wherein the bottom face is in contact with a top face of the first conductive part, the vertical face has one end connected with the bottom face and one end away from the bottom face connected with the inclined face.

4. The manufacturing method of the semiconductor structure of claim 2, wherein the air gap is formed between each of the bit line structures and the conductive plug, and the inclined face is at least partially exposed to the air gap.

5. The manufacturing method of the semiconductor structure of claim 2, wherein
two inclined faces are provided and are respectively located on two sides of the bottom of the second conductive part facing the adjacent bit line structures.

6. The manufacturing method of the semiconductor structure of claim 2, wherein
a perpendicular distance between a vertex angle of the conductive barrier block and the inclined face is greater than a perpendicular distance between a vertex angle of the conductive structure and the inclined face.

7. The manufacturing method of the semiconductor structure of claim 6, wherein a top of the conductive barrier block is higher than a bottom of the inclined face.

8. The manufacturing method of the semiconductor structure of claim 6, wherein the width of the conductive barrier block is ⅓ to ½ of the width of the conductive structure.

9. The manufacturing method of the semiconductor structure of claim 7, wherein the width of the conductive barrier block is ⅓ to ½ of the width of the conductive structure.

10. The manufacturing method of the semiconductor structure of claim 1, wherein a material of the conductive barrier block comprises metal-rich nitride or metal-rich silicide.

11. A semiconductor structure, comprising:
a substrate;
a plurality of bit line structures distributed at intervals on the substrate, wherein each of the bit line structures comprises a conductive structure, a conductive barrier block and an insulative structure which are stacked sequentially, and a width of the conductive barrier block is less than a width of the conductive structure; and
an air gap in contact with a side wall of each of the bit line structures.

12. The semiconductor structure of claim 11, further comprising:
a conductive plug located on the substrate between adjacent bit line structures, wherein the conductive plug comprises a first conductive part and a second conductive part located above the first conductive part,
wherein a bottom of the second conductive part has an inclined face facing the bit line structures.

13. The semiconductor structure of claim 12, wherein
the bottom of the second conductive part further comprises a bottom face and a vertical face between the bottom face and the inclined face, wherein the bottom face is in contact with a top face of the first conductive part, the vertical face has one end connected with the bottom face and one end away from the bottom face connected with the inclined face.

14. The semiconductor structure of claim 12, wherein the air gap is formed between each of the bit line structures and the conductive plug, and the inclined face is at least partially exposed to the air gap.

15. The semiconductor structure of claim 12, wherein
two inclined faces are provided and are respectively located on two sides of the bottom of the second conductive part facing the adjacent bit line structures.

16. The semiconductor structure of claim 12, wherein a perpendicular distance between a vertex angle of the conductive barrier block and the inclined face is greater than a perpendicular distance between a vertex angle of the conductive structure and the inclined face.

17. The semiconductor structure of claim 16, wherein the width of the conductive barrier block is ⅓ to ½ of the width of the conductive structure.

18. The semiconductor structure of claim 11, wherein a material of the conductive barrier block comprises metal-rich nitride or metal-rich silicide.
